(19) United States
(12) Patent Application Publication
(10) Pub. No.: US 2018/0155834 A1
(43) Pub. Date: Jun. 7, 2018

(54) Integrated Atomic Layer Deposition Tool

(71) Applicant: Applied Materials, Inc., Santa Clara, CA (US)

(72) Inventors: Mukund Srinivasan, Fremont, CA (US); Hari Ponnekanti, San Jose, CA (US); Joseph Yudovsky, Campbell, CA (US); Alexander S. Polyak, Palm Coast, FL (US)

(21) Appl. No.: 15/827,498

(22) Filed: Nov. 30, 2017

Related U.S. Application Data
(60) Provisional application No. 62/429,215, filed on Dec. 2, 2016.

(51) Int. Cl. C23C 16/455; H01L 21/285; H01L 21/67; H01L 21/02

(52) U.S. Cl. CPC C23C 16/45544; H01L 21/28562; C23C 16/45542; H01L 21/67167; H01L 21/67098; H01L 21/02005; C23C 16/45534

(57) ABSTRACT

Processing platforms having a central transfer station with a robot, a first batch processing chamber connected to a first side of the central transfer station and a first single wafer processing chamber connected to a second side of the central transfer station, where the first batch processing chamber configured to process x wafers at a time for a batch time and the first single wafer processing chamber configured to process a wafer for about 1/x of the batch time. Methods of using the processing platforms and processing a plurality of wafers are also described.

### CROSS-REFERENCE TO RELATED APPLICATIONS

This application claims priority to U.S. Provisional Application No. 62/429,215, filed Dec. 2, 2016, the entire disclosure of which is hereby incorporated by reference herein.

### TECHNICAL FIELD

The present disclosure relates generally to apparatus and methods for depositing thin films. In particular, the disclosure relates to integrated atomic layer deposition batch processing tools and methods of use.

### BACKGROUND

Integrated circuits are made possible by processes which produce intricately patterned material layers on substrate surfaces. Producing patterned materials on a substrate requires controlled methods for deposition and removal of material layers. Modern semiconductor manufacturing processing applies increasing emphasis on the integration of films without air breaks between process steps. Such a requirement poses a challenge for equipment manufacturers to allow integration of various process chambers into a single tool.

One process that has become popular for deposition of thin films is atomic layer deposition (ALD). Atomic layer deposition is a method in which a substrate is exposed to a precursor which chemisorbs to the substrate surface followed by a reactant which reacts with the chemisorbed precursor. ALD processes are self-limiting and can provide molecular level control of film thicknesses. However, ALD processing can be time consuming due to the need to purge the reaction chamber between exposures to the precursors and reactants.

Therefore, there is a need in the art for apparatus and methods to efficiently deposit films for semiconductor manufacturing.

### SUMMARY

One or more embodiments of the disclosure are directed to processing platforms comprising a central transfer station having a robot therein. The central transfer station has a plurality of sides. A first batch processing chamber is connected to a first side of the central transfer station. The first batch processing chamber is configured to process x wafers at a time for a batch time. A first single wafer processing chamber is connected to a second side of the central transfer station. The first single wafer processing chamber is configured to process a wafer for about 1/x of the batch time

Additional embodiments of the disclosure are directed to processing platforms comprising a central transfer station having a robot therein. The central transfer station has a plurality of sides. The robot has a first arm and a second arm. A first batch processing chamber is connected to a first side of the central transfer station. The first batch processing chamber is configured to process x wafers at a time for a batch time. A first single wafer processing chamber is connected to a second side of the central transfer station. The first single wafer processing chamber is configured to process a wafer for about 1/x of the batch time. A second batch processing chamber is connected to a third side of the central transfer station. The second batch processing chamber is configured to process y wafers at a time for a second batch time. A second single wafer processing chamber is connected to a fourth side of the central transfer station. The second single wafer processing chamber is configured to process a wafer for about 1/y of the second batch time. A first buffer station is connected to a fifth side of the central transfer station. A second buffer station is connected to a sixth side of the central transfer station. A slit valve is positioned between processing chamber and the central transfer station. A controller is connected to the robot and configured to move wafers between the first single wafer processing chamber and the first batch processing chamber with the first arm of the robot and to move wafers between the second single wafer processing chamber and the second batch processing chamber with the second arm of the robot. The controller is configured to move wafers between the first buffer station and one or more of the first single wafer processing chamber or first batch processing chamber using the first arm and to move wafers between the second buffer station and one or more of the second single wafer processing chamber or the second batch processing chamber using the second arm. Each of the processing chambers further comprises a plurality of access doors on sides of the processing chamber to allow manual access to the processing chamber without removing the processing chamber from the central transfer station. A single power connector provides power to each of the processing chambers and the central transfer station.

Further embodiments of the disclosure are directed to methods of batch processing a plurality of semiconductor wafers. The methods comprise:
(a1) positioning a wafer in a first single wafer processing chamber using a first arm of a robot;
(b1) processing the wafer in the first single wafer processing chamber for 1/x of a first batch time;
(c1) moving the wafer processed in the first single wafer processing chamber to a first batch processing chamber using the first arm, the first batch processing chamber configured to process x wafers at a time for the first batch time;
(d1) repeating (a1) through (c1) until the first batch processing chamber is loaded with x wafers;
(e1) positioning a wafer in the first single wafer processing chamber using the first robot;
(f1) processing the wafer in the first single wafer processing chamber;
(g1) removing a wafer from the first batch processing chamber to open a process space in the first batch processing chamber;
(h1) moving the wafer from the first single wafer processing chamber to the open process space in the first batch processing chamber; and
(i1) repeating (e1) through (h1) until a predetermined number of wafers have been processed through each of the first single wafer processing chamber and the first batch processing chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic view of a processing platform in accordance with one or more embodiment of the disclosure;

FIG. 2 shows a cross-sectional view of a batch processing chamber in accordance with one or more embodiment of the disclosure;

FIG. 3 shows a partial perspective view of a batch processing chamber in accordance with one or more embodiment of the disclosure;

FIG. 4 shows a schematic view of a batch processing chamber in accordance with one or more embodiment of the disclosure;

FIG. 5 shows a schematic view of a portion of a wedge shaped gas distribution assembly for use in a batch processing chamber in accordance with one or more embodiment of the disclosure;

FIG. 6 shows a schematic view of a batch processing chamber in accordance with one or more embodiment of the disclosure; and

FIGS. 7A through 7C illustrate an exemplary process sequence in accordance with one or more embodiment of the disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “wafer” or “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Embodiments of the disclosure provide an atomic layer deposition platform that allows for the installation of additional non-ALD, or ALD process chambers in addition to one or two batch processing chambers. Some embodiments advantageously provide a platform that can be an extension of another platform, e.g., a cluster tool like Producer® GT™ from Applied Materials, Inc., Santa Clara, Calif. Some embodiments further extend the capability to perform various processes of film deposition or removal without need to transport wafers outside of the system until completion. Some embodiments can be advantageously used with selective deposition and etch processes without air breaks.

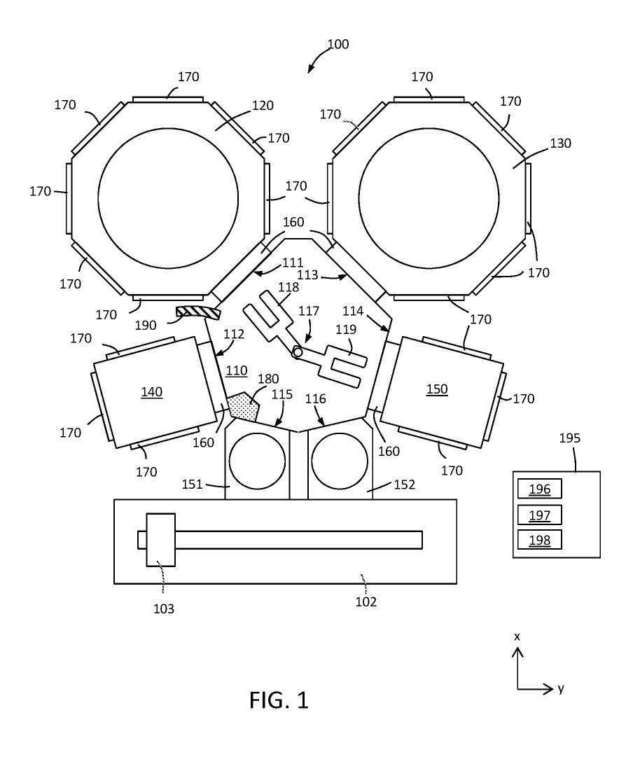

FIG. 1 shows a processing platform 100 in accordance with one or more embodiment of the disclosure. The embodiment shown in FIG. 1 is merely representative of one possible configuration and should not be taken as limiting the scope of the disclosure. For example, in some embodiments, the processing platform 100 has different numbers of process chambers, buffer chambers and robot configurations.

The processing platform 100 includes a central transfer station 110 which has a plurality of sides 111, 112, 113, 114, 115, 116. The transfer station 110 shown has a first side 111, a second side 112, a third side 113, a fourth side 114, a fifth side 115 and a sixth side 116. Although six sides are shown, those skilled in the art will understand that there can be any suitable number of sides to the transfer station 110 depending on, for example, the overall configuration of the processing platform 100. In some embodiments, the central transfer station 110 has four sides. In some embodiments, the central transfer station 110 has four sides with two access doors per side to allow two process chambers (including buffer chambers) to be connected to each side of the central transfer station 110.

The transfer station 110 has a robot 117 positioned therein. The robot 117 can be any suitable robot capable of moving a wafer during processing. In some embodiments, the robot 117 has a first arm 118 and a second arm 119. The first arm 118 and second arm 119 can be moved independently of the other arm. The first arm 118 and second arm 119 can move in the x-y plane and/or along the z-axis. In some embodiments, the robot 117 includes a third arm or a fourth arm (not shown). Each of the arms can move independently of other arms. In some embodiments, the arms are connected to separate robots.

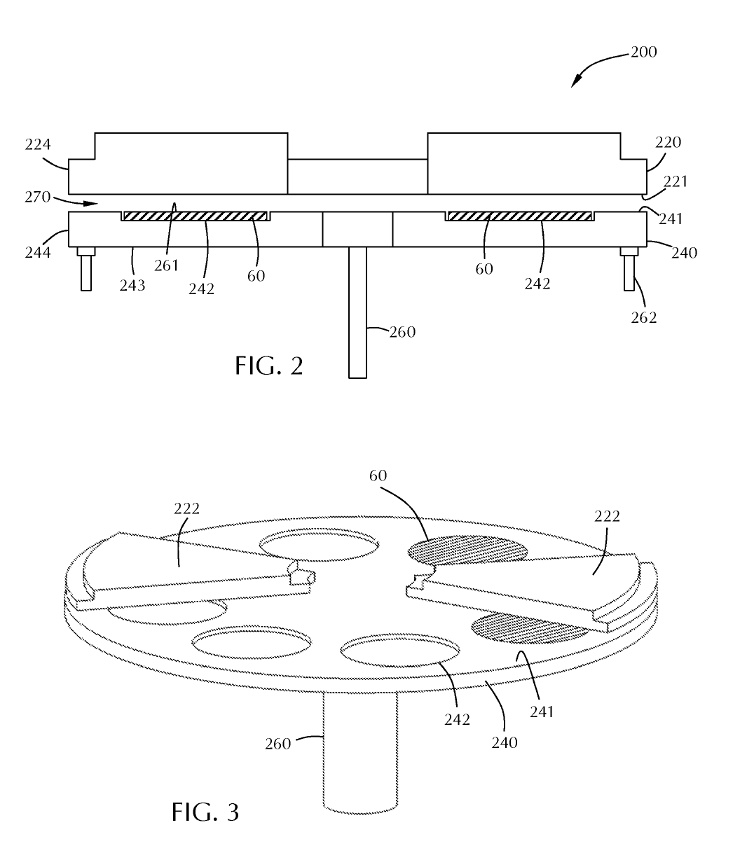

A first batch processing chamber 120 can be connected to a first side 111 of the central transfer station 110. The first batch processing chamber 120 can be configured to process x wafers at a time for a batch time. In some embodiments, the first batch processing chamber 120 can be configured to process in the range of about four (x=4) to about 12 (x=12) wafers at the same time. In some embodiments, the first batch processing chamber 120 is configured to process six (x=6) wafers at the same time. As will be understood by the skilled artisan, while the batch processing chamber 120 can process multiple wafers between loading/unloading of an individual wafer, each wafer may be subjected to different process conditions at any given time. For example, a spatial atomic layer deposition chamber, like that shown in FIGS. 2 through 6, expose the wafers to different process conditions in different processing regions so that as a wafer is moved through each of the regions, the process is completed.

FIG. 2 shows a cross-section of a processing chamber 200 including a gas distribution assembly 220, also referred to as injectors or an injector assembly, and a susceptor assembly 240. The gas distribution assembly 220 is any type of gas delivery device used in a processing chamber. The gas distribution assembly 220 includes a front surface 221 which faces the susceptor assembly 240. The front surface 221 can have any number or variety of openings to deliver a flow of gases toward the susceptor assembly 240. The gas distribution assembly 220 also includes an outer edge 224 which in the embodiments shown, is substantially round.

The specific type of gas distribution assembly 220 used can vary depending on the particular process being used. Embodiments of the disclosure can be used with any type of processing system where the gap between the susceptor and the gas distribution assembly is controlled. While various types of gas distribution assemblies can be employed (e.g., showerheads), embodiments of the disclosure may be particularly useful with spatial gas distribution assemblies which have a plurality of substantially parallel gas channels. As used in this specification and the appended claims, the term “substantially parallel” means that the elongate axis of the gas channels extend in the same general direction. There can be slight imperfections in the parallelism of the gas channels. In a binary reaction, the plurality of substantially parallel gas channels can include at least one first reactive gas A channel, at least one second reactive gas B channel, at least one purge gas P channel and/or at least one vacuum V channel. The gases flowing from the first reactive gas A channel(s), the second reactive gas B channel(s) and the purge gas P channel(s) are directed toward the top surface of the wafer. Some of the gas flow moves horizontally across the surface of the wafer and out of the process region through the purge gas P channel(s). A substrate moving from one end of the gas distribution assembly to the other end will be exposed to each of the process gases in turn, forming a layer on the substrate surface.

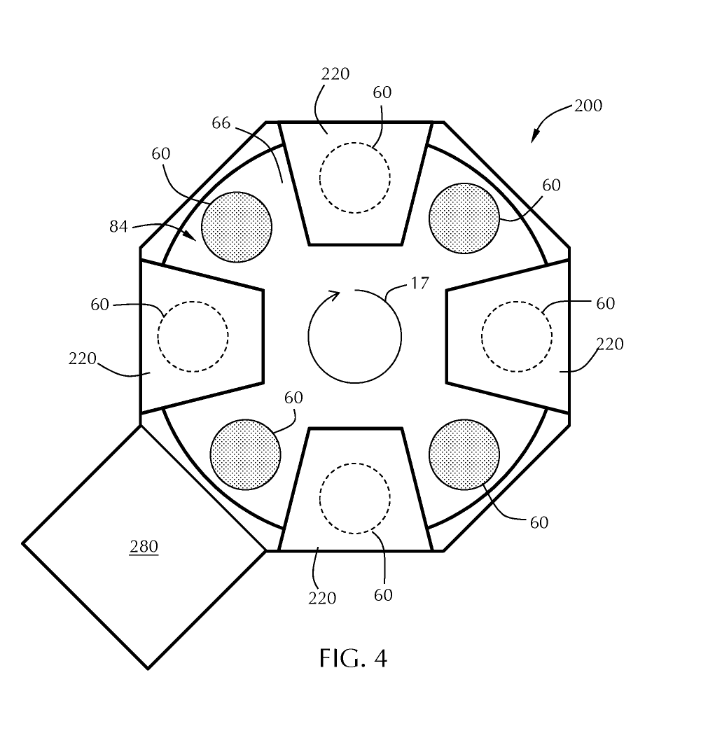

In some embodiments, the gas distribution assembly 220 is a rigid stationary body made of a single injector unit. In one or more embodiments, the gas distribution assembly 220 is made up of a plurality of individual sectors (e.g., injector units 222), as shown in FIG. 3. Either a single piece body or a multi-sector body can be used with the various embodiments of the disclosure described.

A susceptor assembly 240 is positioned beneath the gas distribution assembly 220. The susceptor assembly 240 includes a top surface 241 and at least one recess 242 in the top surface 241. The susceptor assembly 240 also has a bottom surface 243 and an edge 244. The recess 242 can be any suitable shape and size depending on the shape and size of the substrates 60 being processed. In the embodiment shown in FIG. 2, the recess 242 has a flat bottom to support the bottom of the wafer; however, the bottom of the recess can vary. In some embodiments, the recess has step regions around the outer peripheral edge of the recess which are sized to support the outer peripheral edge of the wafer. The amount of the outer peripheral edge of the wafer that is supported by the steps can vary depending on, for example, the thickness of the wafer and the presence of features already present on the back side of the wafer.

In some embodiments, as shown in FIG. 2, the recess 242 in the top surface 241 of the susceptor assembly 240 is sized so that a substrate 60 supported in the recess 242 has a top surface 61 substantially coplanar with the top surface 241 of the susceptor 240. As used in this specification and the appended claims, the term “substantially coplanar” means that the top surface of the wafer and the top surface of the susceptor assembly are coplanar within ±0.2 mm. In some embodiments, the top surfaces are coplanar within 0.5 mm, ±0.4 mm, ±0.35 mm, ±0.30 mm, ±0.25 mm, ±0.20 mm, ±0.15 mm, ±0.10 mm or ±0.05 mm.

The susceptor assembly 240 of FIG. 2 includes a support post 260 which is capable of lifting, lowering and rotating the susceptor assembly 240. The susceptor assembly may include a heater, or gas lines, or electrical components within the center of the support post 260. The support post 260 may be the primary means of increasing or decreasing the gap between the susceptor assembly 240 and the gas distribution assembly 220, moving the susceptor assembly 240 into proper position. The susceptor assembly 240 may also include fine tuning actuators 262 which can make micro-adjustments to susceptor assembly 240 to create a predetermined gap 270 between the susceptor assembly 240 and the gas distribution assembly 220.

In some embodiments, the gap 270 distance is in the range of about 0.1 mm to about 5.0 mm, or in the range of about 0.1 mm to about 3.0 mm, or in the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

The processing chamber 200 shown in the Figures is a carousel-type chamber in which the susceptor assembly 240 can hold a plurality of substrates 60. As shown in FIG. 3, the gas distribution assembly 220 may include a plurality of separate injector units 222, each injector unit 222 being capable of depositing a film on the wafer, as the wafer is moved beneath the injector unit. Two pie-shaped injector units 222 are shown positioned on approximately opposite sides of and above the susceptor assembly 240. This number of injector units 222 is shown for illustrative purposes only. It will be understood that more or less injector units 222 can be included. In some embodiments, there are a sufficient number of pie-shaped injector units 222 to form a shape conforming to the shape of the susceptor assembly 240. In some embodiments, each of the individual pie-shaped injector units 222 may be independently moved, removed and/or replaced without affecting any of the other injector units 222. For example, one segment may be raised to permit a robot to access the region between the susceptor assembly 240 and gas distribution assembly 220 to load/unload substrates 60.

Processing chambers having multiple gas injectors can be used to process multiple wafers simultaneously so that the wafers experience the same process flow. For example, as shown in FIG. 4, the processing chamber 200 has four gas injector assemblies and four substrates 60. At the outset of processing, the substrates 60 can be positioned between the gas distribution assemblies 220. Rotating 17 the susceptor assembly 240 by 45° will result in each substrate 60 which is between gas distribution assemblies 220 to be moved to an gas distribution assembly 220 for film deposition, as illustrated by the dotted circle under the gas distribution assemblies 220. An additional 45° rotation would move the substrates 60 away from the gas distribution assemblies 220. The number of substrates 60 and gas distribution assemblies 220 can be the same or different. In some embodiments, there are the same numbers of wafers being processed as there are gas distribution assemblies. In one or more embodiments, the number of wafers being processed are fraction of or an integer multiple of the number of gas distribution assemblies. For example, if there are four gas distribution assemblies, there are 4x wafers being processed, where x is an integer value greater than or equal to one. In an exemplary embodiment, the gas distribution assembly 220 includes eight process regions separated by gas curtains and the susceptor assembly 240 can hold six wafers.

The processing chamber 200 shown in FIG. 4 is merely representative of one possible configuration and should not be taken as limiting the scope of the disclosure. Here, the processing chamber 200 includes a plurality of gas distribution assemblies 220. In the embodiment shown, there are four gas distribution assemblies 220 (also called injector assemblies) evenly spaced about the processing chamber 200. The processing chamber 200 shown is octagonal; however, those skilled in the art will understand that this is one possible shape and should not be taken as limiting the scope of the disclosure. The gas distribution assemblies 220 shown are trapezoidal, but can be a single circular component or made up of a plurality of pie-shaped segments, like that shown in FIG. 3.

The embodiment shown in FIG. 4 includes a load lock chamber 280, or an auxiliary chamber like a buffer station. This chamber 280 is connected to a side of the processing chamber 200 to allow, for example the substrates (also referred to as substrates 60) to be loaded/unloaded from the chamber 200. A wafer robot may be positioned in the chamber 280 to move the substrate onto the susceptor.

Rotation of the carousel (e.g., the susceptor assembly 240) can be continuous or intermittent (discontinuous). In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where the carousel can pause again. Pausing between the injectors may provide time for additional processing steps between each layer deposition (e.g., exposure to plasma).

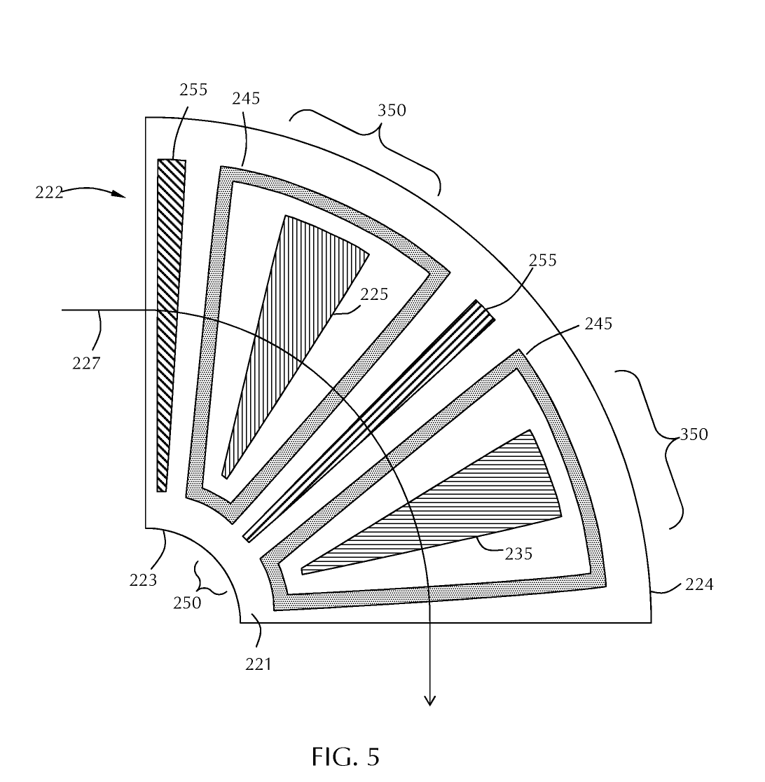

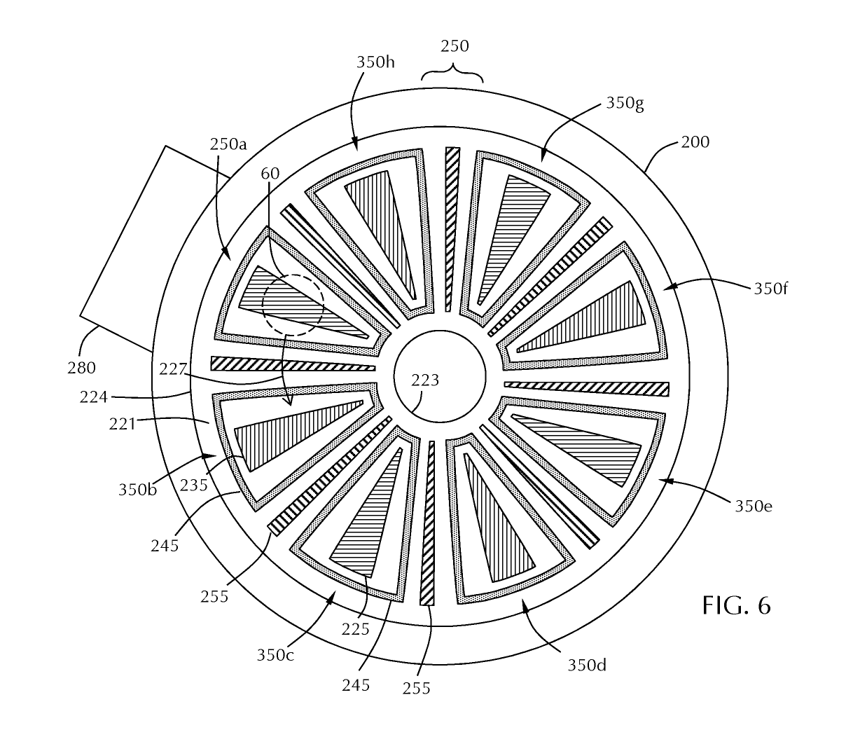

FIG. 5 shows a sector or portion of a gas distribution assembly 220, which may be referred to as an injector unit 222. The injector units 222 can be used individually or in combination with other injector units. For example, as shown in FIG. 6, four of the injector units 222 of FIG. 5 are combined to form a single gas distribution assembly 220. (The lines separating the four injector units are not shown for clarity.) While the injector unit 222 of FIG. 5 has both a first reactive gas port 225 and a second gas port 235 in addition to purge gas ports 255 and vacuum ports 245, an injector unit 222 does not need all of these components.

Referring to both FIGS. 5 and 6, a gas distribution assembly 220 in accordance with one or more embodiment may comprise a plurality of sectors (or injector units 222) with each sector being identical or different. The gas distribution assembly 220 is positioned within the processing chamber and comprises a plurality of elongate gas ports 225, 235, 255 in a front surface 221 of the gas distribution assembly 220. The plurality of elongate gas ports 225, 235, 255 and vacuum ports 245 extend from an area adjacent the inner peripheral edge 223 toward an area adjacent the outer peripheral edge 224 of the gas distribution assembly 220. The plurality of gas ports shown include a first reactive gas port 225, a second gas port 235, a vacuum port 245 which surrounds each of the first reactive gas ports and the second reactive gas ports and a purge gas port 255.

With reference to the embodiments shown in FIG. 5 or 6, when stating that the ports extend from at least about an inner peripheral region to at least about an outer peripheral region, however, the ports can extend more than just radially from inner to outer regions. The ports can extend tangentially as vacuum port 245 surrounds reactive gas port 225 and reactive gas port 235. In the embodiment shown in FIGS. 5 and 6, the wedge shaped reactive gas ports 225, 235 are surrounded on all edges, including adjacent the inner peripheral region and outer peripheral region, by a vacuum port 245.

Referring to FIG. 5, as a substrate moves along path 227, each portion of the substrate surface is exposed to the various reactive gases. To follow the path 227, the substrate will be exposed to, or “see”, a purge gas port 255, a vacuum port 245, a first reactive gas port 225, a vacuum port 245, a purge gas port 255, a vacuum port 245, a second gas port 235 and a vacuum port 245. Thus, at the end of the path 227 shown in FIG. 5, the substrate has been exposed to the first reactive gas 225 and the second reactive gas 235 to form a layer. The injector unit 222 shown makes a quarter circle but could be larger or smaller. The gas distribution assembly 220 shown in FIG. 6 can be considered a combination of four of the injector units 222 of FIG. 4 connected in series.

The injector unit 222 of FIG. 5 shows a gas curtain 250 that separates the reactive gases. The term “gas curtain” is used to describe any combination of gas flows or vacuum that separate reactive gases from mixing. The gas curtain 250 shown in FIG. 5 comprises the portion of the vacuum port 245 next to the first reactive gas port 225, the purge gas port 255 in the middle and a portion of the vacuum port 245 next to the second gas port 235. This combination of gas flow and vacuum can be used to prevent or minimize gas phase reactions of the first reactive gas and the second reactive gas.

Referring to FIG. 6, the combination of gas flows and vacuum from the gas distribution assembly 220 form a separation into a plurality of process regions 350. The process regions are roughly defined around the individual reactive gas ports 225, 235 with the gas curtain 250 between 350. The embodiment shown in FIG. 6 makes up eight separate process regions 350 with eight separate gas curtains 250 between. A processing chamber can have at least two process regions. In some embodiments, there are at least three, four, five, six, seven, eight, nine, 10, 11 or 12 process regions.

During processing a substrate may be exposed to more than one process region 350 at any given time. However, the portions that are exposed to the different process regions will have a gas curtain separating the two. For example, if the leading edge of a substrate enters a process region including the second gas port 235, a middle portion of the substrate will be under a gas curtain 250 and the trailing edge of the substrate will be in a process region including the first reactive gas port 225.

A factory interface 280, which can be, for example, a load lock chamber, is shown connected to the processing chamber 200. A substrate 60 is shown superimposed over the gas distribution assembly 220 to provide a frame of reference. The substrate 60 may often sit on a susceptor assembly to be held near the front surface 221 of the gas distribution plate 220. The substrate 60 is loaded via the factory interface 280 into the processing chamber 200 onto a substrate support or susceptor assembly (see FIG. 4). The substrate 60 can be shown positioned within a process region because the substrate is located adjacent the first reactive gas port 225 and between two gas curtains 250a, 250b. Rotating the substrate 60 along path 227 will move the substrate counter-clockwise around the processing chamber 200. Thus, the substrate 60 will be exposed to the first process region 350a through the eighth process region 350h, including all process regions between.

Embodiments of the disclosure are directed to processing methods comprising a processing chamber 200 with a plurality of process regions 350a-350h with each process region separated from an adjacent region by a gas curtain 250. For example, the processing chamber shown in FIG. 6. The number of gas curtains and process regions within the processing chamber can be any suitable number depending on the arrangement of gas flows. The embodiment shown in FIG. 6 has eight gas curtains 250 and eight process regions 350a-350h.

Referring back to FIG. 1, the processing platform 100 includes a first single wafer processing chamber 140 (SWPC) connected to a second side 112 of the central transfer station 110. The first single wafer processing chamber 140 is configured to process a wafer for about 1/x of the batch time (of the first batch processing chamber). For example, if the batch process chamber 120 takes 12 minutes to process six wafers, the first single wafer processing chamber 140 is configured to take about two minutes (i.e., ⅙ of 12) to process a wafer.

The single wafer processing chamber 140 can be any suitable processing chamber configured to process one wafer at a time. Suitable single wafer processing chambers include, but are not limited to, chemical vapor deposition (CVD) chamber, an atomic layer deposition (ALD) chamber, a physical vapor deposition (PVD) chamber, a rapid thermal processing (RTP) chamber, an annealing chamber, a cleaning chamber or a buffer chamber.

In some embodiments, the processing platform further comprises a second batch processing chamber 130 connected to a third side 113 of the central transfer station 110. The second batch processing chamber 130 can be configured to process y wafers at a time for a second batch time.

The second batch processing chamber 130 can be the same as the first batch processing chamber 120 or different. In some embodiments, the first batch processing chamber 120 and the second batch processing chamber 130 are configured to perform the same process with the same number of wafers in the same batch time so that x and y are the same and the first batch time and second batch time are the same. In some embodiments, the first batch processing chamber 120 and the second batch processing chamber 130 are configured to have one or more of different numbers of wafers (x not equal to y), different batch times, or both.

In the embodiment shown in FIG. 1, the processing platform 100 includes a second single wafer processing chamber 150 connected to a fourth side 114 of the central transfer station 110. The second single wafer processing chamber 150 is configured to process a wafer for about 1/y of the second batch time.

The second single wafer processing chamber 150 can be the same as the first single wafer processing chamber 140 or different. In some embodiments, the first and second batch processing chambers 120, 130 are configured to process the same number of wafers in the same batch time (x=y) and the first and second single wafer processing chambers 140, 150 are configured to perform the same process in the same amount of time (1/x=1/y).

The processing platform 100 can include a controller 195 connected to the robot 117 (the connection is not shown). The controller 195 can be configured to move wafers between the first single wafer processing chamber 140 and the first batch processing chamber 120 with a first arm 118 of the robot 117. In some embodiments, the controller 195 is also configured to move wafers between the second single wafer processing chamber 150 and the second batch processing chamber 130 with a second arm 119 of the robot 117. As used in this manner, moving between two chambers means that the robot can move a wafer back and forth from a first chamber to a second chamber.

The processing platform 100 can also include a first buffer station 151 connected to a fifth side 115 of the central transfer station 110 and/or a second buffer station 152 connected to a sixth side 116 of the central transfer station 110. The first buffer station 151 and second buffer station 152 can perform the same or different functions. For example, the buffer stations may hold a cassette of wafers which are processed and returned to the original cassette, or the first buffer station 151 may hold unprocessed wafers which are moved to the second buffer station 152 after processing. In some embodiments, one or more of the buffer stations are configured to pre-treat, pre-heat or clean the wafers before and/or after processing.

In some embodiments, the controller 195 is configured to move wafers between the first buffer station 151 and one or more of the first single wafer processing chamber 140 and the first batch processing chamber 120 using the first arm 118 of the robot 117. In some embodiments, the controller 195 is configured to move wafers between the second buffer station 152 and one or more of the second single wafer processing chamber 150 or the second batch processing chamber 130 using the second arm 119 of the robot 117.

The processing platform 100 may also include one or more slit valves 160 between the central transfer station 110 and any of the processing chambers. In the embodiment shown, there is a slit valve 160 between each of the processing chambers 120, 130, 140, 150 and the central transfer station 110. The slit valves 160 can open and close to isolate the environment within the processing chamber from the environment within the central transfer station 110. For example, if the processing chamber will generate plasma during processing, it may be helpful to close the slit valve for that processing chamber to prevent stray plasma from damaging the robot in the transfer station.

In some embodiments, the processing chambers are not readily removable from the central transfer station 110. To allow maintenance to be performed on any of the processing chambers, each of the processing chambers may further include a plurality of access doors 170 on sides of the processing chambers. The access doors 170 allow manual access to the processing chamber without removing the processing chamber from the central transfer station 110. In the embodiment shown, each side of each of the processing chamber, except the side connected to the transfer station, have an access door 170. The inclusion of so many access doors 170 can complicate the construction of the processing chambers employed because the hardware within the chambers would need to be configured to be accessible through the doors.

The processing platform of some embodiments includes a water box 180 connected to the transfer station 110. The water box 180 can be configured to provide a coolant to any or all of the processing chambers. Although referred to as a “water” box, those skilled in the art will understand that any coolant can be used.

The size of the processing platform 100 can be cumbersome and difficult to connect to house power and gas supplies. In some embodiments, a single power connector 190 connects to the processing platform 100 to provide power to each of the processing chambers and the central transfer station 110.

The processing platform 100 can be connected to a factory interface 102 to allow wafers or cassettes of wafers to be loaded into the platform 100. A robot 103 within the factory interface 102 can be moved the wafers or cassettes into and out of the buffer stations 151, 152. The wafers or cassettes can be moved within the platform 100 by the robot 117 in the central transfer station 110. In some embodiments, the factory interface 102 is a transfer station of another cluster tool.

The controller 195 may be provided and coupled to various components of the processing platform 100 to control the operation thereof. The controller 195 can be a single controller that controls the entire processing platform 100, or multiple controllers that control individual portions of the processing platform 100. For example, the processing platform 100 may include separate controllers for each of the individual processing chambers, central transfer station, factory interface and robots. In some embodiments, the controller 195 includes a central processing unit (CPU) 196, a memory 197, and support circuits 198. The controller 195 may control the processing platform 100 directly, or via computers (or controllers) associated with particular process chamber and/or support system components. The controller 195 may be one of any form of general-purpose computer processor that can be used in an industrial setting for controlling various chambers and sub-processors. The memory 197 or computer readable medium of the controller 195 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 198 are coupled to the CPU 196 for supporting the processor in a conventional manner. These circuits include cache, power supplies, clock circuits, input/output circuitry and subsystems, and the like. One or more processes may be stored in the memory 198 as software routine that may be executed or invoked to control the operation of the processing platform 100 or individual processing chambers in the manner described herein. The software routine may also be stored and/or executed by a second CPU (not shown) that is remotely located from the hardware being controlled by the CPU 196. The controller 195 can include one or more configurations which can include any commands or functions to control flow rates, gas valves, gas sources, rotation, movement, heating, cooling, or other processes for performing the various configurations.

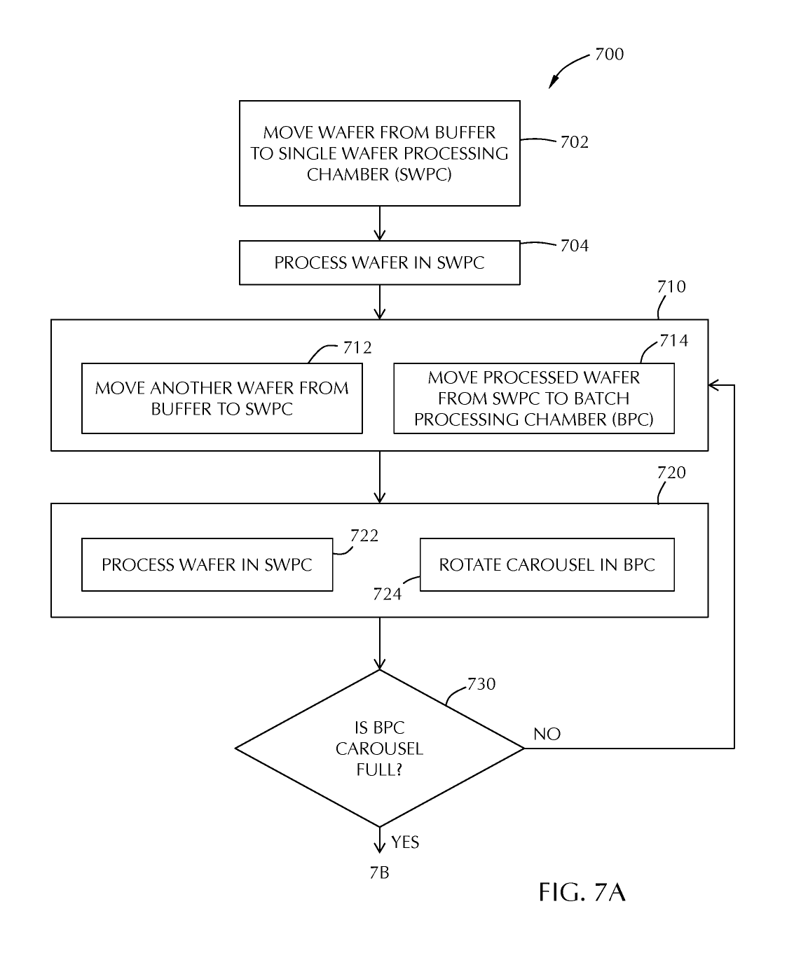

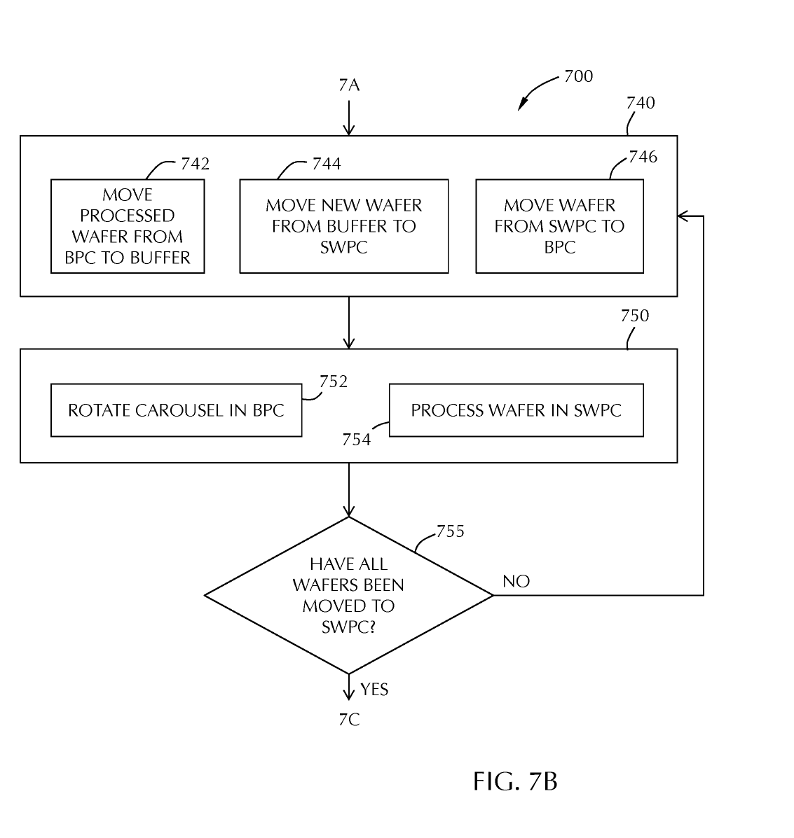

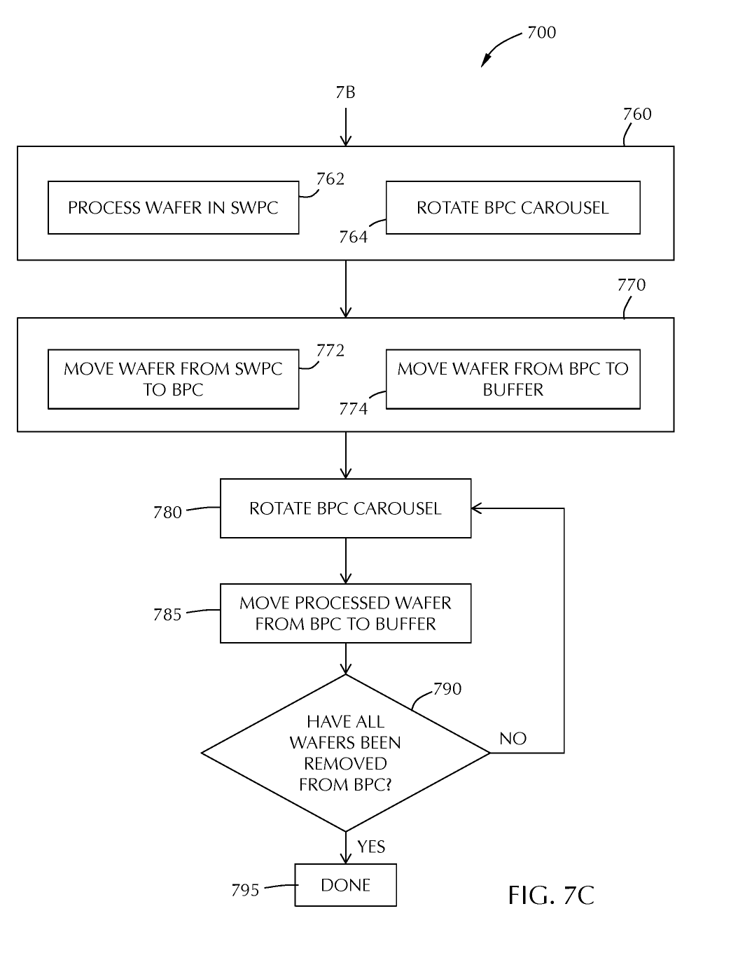

Referring to FIGS. 7A through 7C, one or more embodiments of the disclosure are directed to methods 700 of batch processing a plurality of semiconductor wafers. A wafer or pluralities of wafers are loaded into the buffer station either through a factory interface, manually or through a separate cluster tool.

Starting at FIG. 7A, in 702, a wafer is moved from the buffer station to a single wafer processing chamber (SWPC). The process described can be performed at the same time in both the first and second sets of process chambers, or can be separated into different processes. The wafer is moved from the buffer station to the SWPC by a first arm of a robot located within the central transfer station.

At 704, the wafer is processed in the first single wafer processing chamber for 1/x of a first batch time. The first batch time is the time taken to process x wafers in the batch process chamber (BPC) employed after the SWPC.

At 710 multiple processes occur which can be either simultaneous or in either order. At 712, another wafer is moved from the buffer station to the SW PC. At 714, the processed wafer is moved from the SWPC to the BPC. Movement of the wafers can be performed by the same robot arm so that the 712 and 714 are performed in sequence with 714 being first to provide an empty chamber SWPC chamber. In some embodiments, the movements of the wafers are performed by different arms of the robot (or different robots) so that the movements can be coordinated to decrease the time for transfers.

At 720 multiple processes occur at about the same time. In 722, the wafer in the SWPC is processed for 1/x of the batch time. In 724, a carousel (i.e., a susceptor assembly) is rotated within the BPC to allow a first part of the process to be performed in the BPC. The BPC can process x wafers in an amount of time referred to as the batch time.

The process is repeated until the first batch processing chamber is loaded with x wafers. In 730, a decision point is reached where the batch processing chamber loading is queried. If the batch processing chamber is full; meaning that it has x wafers loaded on the carousel, the method continues on FIG. 7B. If the BPC is not full—has less than x wafers on the carousel—the cycle repeats 710 and 720 until the decision point of 730 is true.

Moving to the part of the method 700 described in FIG. 7B, at 740, multiple individual phases occur which can be sequential, simultaneous, overlapping or a combination thereof. At 742, a processed wafer is unloaded from the batch processing chamber carousel and moved to the buffer station. Removing the wafer from the first batch processing chamber opens a process space in the first batch processing chamber for another wafer to be loaded. The buffer station can be same buffer station that the wafer originally entered the processing platform through, or a different buffer station.

At 744, a new wafer is moved from buffer station to the single wafer processing chamber. At 746, the wafer processed by the single wafer processing chamber is moved to the open process space of the batch processing chamber and positioned on the carousel. The wafers can be moved by the same robot arm or by different robot arms, or by different robots. When the same robot arm is used to move all of the wafers, the order of the movement is coordinated so that there is an open position created in each process chamber before the next wafer is moved to that chamber.

At 750, processing occurs in both the single wafer processing chamber 754 and in the batch processing chamber by rotating the carousel of the BPC 752.

At 752, another decision point is reached to determine if all of the wafers have been moved from the buffer station to at least the single wafer processing chamber. If not all of the wafers have reached the single wafer processing chamber, 740 and 750 are repeated until the predetermined numbers of wafers have been moved to the single wafer processing chamber. Once all of the wafers have been moved to the single wafer processing chamber, the method continues to FIG. 7C.

Referring to FIG. 7C, at 760, the wafer in the SWPC is processed 762 and the carousel of the BPC is rotated 764. At 770, the wafer processed in the SWPC is moved to the BPC 772 and a wafer processed by the BPC is moved to the buffer station 774. At this point in the process, the last wafer has been removed from the SWPC.

At 780, the carousel of the batch processing chamber is rotated to continue processing. At 785, a wafer is removed from the carousel of the BPC and transferred to the buffer station. At 790, a decision point is reached to determine if all of the wafers have been removed from the batch processing chamber. If not, 780 and 785 are repeated until the predetermined numbers of wafers have been processed through each of the first single wafer processing chamber and the first batch processing chamber.

Once all of the wafers have been unloaded form the batch process chamber, the process is completed 795 and any additional processing can occur. For example, the wafers can be transferred to another processing platform for additional process steps to be performed.

In some embodiments, both the first single wafer processing chamber 140 and first batch processing chamber 120 are utilized at the same time as the second single wafer processing chamber 150 and the second batch processing chamber 130. The process sequence for the second processing chambers is the same as for the first processing chambers. If the second batch processing chamber is configured to perform a different process than the first batch processing chamber, the timing of the robots can be coordinated to operate both processes simultaneously. If both the first and second batch process chambers and the first and second single wafer processing chambers are configured to perform the same process, the start times of each process can be staggered so that the robot arms can efficiently move the wafers for both process trains without interference. In some embodiments, the processes occurring in the first process train (the first single wafer process chamber and the first batch process chamber) is moved along by the first robot arm while the second robot arm is operating the second process train (the second single wafer process chamber and the second batch process chamber).

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A processing platform comprising:
a central transfer station having a robot therein, the central transfer station having a plurality of sides;
a first batch processing chamber connected to a first side of the central transfer station, the first batch processing chamber configured to process x wafers at a time for a batch time; and
a first single wafer processing chamber connected to a second side of the central transfer station, the first single wafer processing chamber configured to process a wafer for about 1/x of the batch time.

2. The processing platform of claim 1, further comprising a second batch processing chamber connected to a third side of the central transfer station.

3. The processing platform of claim 2, further comprising a second single wafer processing chamber connected to a fourth side of the central transfer station.

4. The processing platform of claim 3, wherein the robot comprises a first arm and a second arm, the first arm and second arm independently movable.

5. The processing platform of claim 4, further comprising a controller connected to the robot and configured to move wafers between the first single wafer processing chamber and the first batch processing chamber with a first arm of the robot and to move wafers between the second single wafer processing chamber and the second batch processing chamber with a second arm of the robot.

6. The processing platform of claim 4, wherein the second batch processing chamber is configured to process y wafers at a time for a second batch time.

7. The processing platform of claim 6, wherein the second single wafer processing chamber is configured to process a wafer for about 1/y of the second batch time.

8. The processing platform of claim 7, further comprising a first buffer station connected to a fifth side of the central transfer station and a second buffer station connected to a sixth side of the central transfer station.

9. The processing platform of claim 8, wherein the controller is configured to move wafers between the first buffer station and one or more of the first single wafer processing chamber or first batch processing chamber using the first arm.

10. The processing platform of claim 9, wherein the controller is configured to move wafers between the second buffer station and one or more of the second single wafer processing chamber or the second batch processing chamber using the second arm.

11. The processing platform of claim 4, further comprising a slit valve between each of the processing chambers and the central transfer station.

12. The processing platform of claim 11, wherein each of the processing chambers further comprise a plurality of access doors on sides of the processing chamber to allow manual access to the processing chamber without removing the processing chamber from the central transfer station.

13. The processing platform of claim 4, further comprising a water box connected to the central transfer station, the water box configured to provide coolant to each of the processing chambers.

14. The processing platform of claim 4, wherein a single power connector provides power to each of the processing chambers and the central transfer station.

15. A processing platform comprising:
a central transfer station having a robot therein, the central transfer station having a plurality of sides, the robot having a first arm and a second arm;
a first batch processing chamber connected to a first side of the central transfer station, the first batch processing chamber configured to process x wafers at a time for a batch time;
a first single wafer processing chamber connected to a second side of the central transfer station, the first single wafer processing chamber configured to process a wafer for about 1/x of the batch time;
a second batch processing chamber connected to a third side of the central transfer station, the second batch processing chamber configured to process y wafers at a time for a second batch time;
a second single wafer processing chamber connected to a fourth side of the central transfer station, the second single wafer processing chamber configured to process a wafer for about 1/y of the second batch time;
a first buffer station connected to a fifth side of the central transfer station;
a second buffer station connected to a sixth side of the central transfer station;
a slit valve positioned between processing chamber and the central transfer station; and
a controller connected to the robot and configured to move wafers between the first single wafer processing chamber and the first batch processing chamber with the first arm of the robot and to move wafers between the second single wafer processing chamber and the second batch processing chamber with the second arm of the robot,
wherein the controller is configured to move wafers between the first buffer station and one or more of the first single wafer processing chamber or first batch processing chamber using the first arm and to move wafers between the second buffer station and one or more of the second single wafer processing chamber or the second batch processing chamber using the second arm,
wherein each of the processing chambers further comprise a plurality of access doors on sides of the processing chamber to allow manual access to the processing chamber without removing the processing chamber from the central transfer station, and
wherein a single power connector provides power to each of the processing chambers and the central transfer station.

16. A method of batch processing a plurality of semiconductor wafers, the method comprising:
(j1) positioning a wafer in a first single wafer processing chamber using a first arm of a robot;
(k1) processing the wafer in the first single wafer processing chamber for 1/x of a first batch time;
(l1) moving the wafer processed in the first single wafer processing chamber to a first batch processing chamber using the first arm, the first batch processing chamber configured to process x wafers at a time for the first batch time;
(m1) repeating (a1) through (c1) until the first batch processing chamber is loaded with x wafers;
(n1) positioning a wafer in the first single wafer processing chamber using the first arm of the robot;
(o1) processing the wafer in the first single wafer processing chamber;
(p1) removing a wafer from the first batch processing chamber to open a process space in the first batch processing chamber;
(q1) moving the wafer from the first single wafer processing chamber to the open process space in the first batch processing chamber; and
(r1) repeating (e1) through (h1) until a predetermined number of wafers have been processed through each of the first single wafer processing chamber and the first batch processing chamber.

17. The method of claim 16, further comprising:
(a2) positioning a wafer in a second single wafer processing chamber using a second arm of a robot;
(b2) processing the wafer in the second single wafer processing chamber for 1/y of a second batch time;
(c2) moving the wafer processed in the second single wafer processing chamber to a second batch processing chamber using the second arm, the second batch processing chamber configured to process y wafers at a time for the second batch time;
(d2) repeating (a2) through (c2) until the second batch processing chamber is loaded with y wafers;
(e2) positioning a wafer in the second single wafer processing chamber using the second robot;
(f2) processing the wafer in the second single wafer processing chamber;
(g2) removing a wafer from the second batch processing chamber to open a process space in the second batch processing chamber;
(h2) moving the wafer from the second single wafer processing chamber to the open process space in the second batch processing chamber; and
(i2) repeating (e2) through (h2) until a predetermined number of wafers have been processed through each of the second single wafer processing chamber and the second batch processing chamber.

18. The method of claim 17, wherein (a1)-(i1) and (a2)-(i2) are performed at about the same time.

19. The method of claim 16, wherein the wafer in (g1) is removed by a second robot arm while the first robot arm is performing (h1).

20. The method of claim 17, wherein the wafer in (g2) is removed by the first robot arm while the second robot arm is performing (h2).
